(19) United States
(12) Patent Application Publication
(10) Pub. No.: US 2026/0106115 A1
(43) Pub. Date: Apr. 16, 2026

(54) PLASMA PROCESS SUPPLY SYSTEM, IN PARTICULAR FOR PULSED PLASMA PROCESSES, AND METHOD FOR OPERATING SUCH A PLASMA PROCESS SUPPLY SYSTEM

(71) Applicant: TRUMPF Hüttinger GmbH + Co. KG, Freiburg (DE)

(72) Inventor: Florian Maier, Pfaffenweiler (DE)

(21) Appl. No.: 19/419,156

(22) Filed: Dec. 15, 2025

Related U.S. Application Data
(63) Continuation of application No. PCT/EP2024/066458, filed on Jun. 13, 2024.

(30) Foreign Application Priority Data
Jun. 16, 2023 (DE) 10 2023 115 791.4

(51) Int. Cl. H01J 37/32

(52) U.S. Cl. CPC H01J 37/32183; H01J 37/32146; H01J 37/32935

(57) ABSTRACT

A plasma process supply system for pulsed plasma processes, including an RF generator including at least one amplifier circuit, an impedance matching circuit, and a controller, the plasma process supply system being configured to connect to a plasma chamber. The RF generator is connected to the impedance matching circuit, the impedance matching circuit being configured to set a target impedance as an input impedance for the RF generator. The controller is configured to set the target impedance such that a trajectory describing an impedance curve for the input impedance within a settling period runs from a starting impedance region through an ignition impedance region to a target impedance region. The RF generator in the ignition impedance region delivers a power level that is higher than a target power level in the target impedance region.

### CROSS REFERENCE TO RELATED APPLICATIONS

This application is a continuation of International Application No. PCT/EP2024/066458 (WO 2024/256588 A1), filed on Jun. 13, 2024, and claims benefit to German Patent Application No. DE 10 2023 115 791.4, filed on Jun. 16, 2023. The aforementioned applications are hereby incorporated by reference herein.

### FIELD

The invention relates to a plasma process supply system and a method for operating such a plasma process supply system.

### BACKGROUND

The surface treatment of workpieces using plasma and gas lasers are industrial methods in which, in particular in a plasma chamber, a plasma is generated either using direct current or a radio-frequency alternating signal having an operating frequency in the range of several tens of kHz up to the GHz range.

The plasma chamber is connected to a radio frequency generator (RF generator) via additional electronic components such as coils, capacitors, cables, or transformers. These additional components can be oscillating circuits, filters, or impedance matching circuits.

Plasma processes represent a highly variable load for the radio frequency generator, depending on the conditions in the plasma chamber. In particular, the properties of the workpiece, electrodes, and gas conditions are taken into account.

Radio frequency generators have a limited operating region with respect to the impedance of the connected electrical load (=consumer). If the load impedance leaves a permissible region, the required energy/power level cannot be delivered to the consumer. Damage to the RF generator is also possible.

For this reason, an impedance matching circuit (matchbox) is usually required to transform the impedance of the load to a nominal impedance of the generator output.

Various impedance matching circuits are known. The impedance matching circuits can be fixed and have a predetermined transformation effect, i.e., they consist of electrical components, in particular coils and capacitors, which are not changed during operation. This is particularly useful for operations that are always consistent, such as with a gas laser. Furthermore, impedance matching circuits are known in which at least some of the components of the impedance matching circuits are mechanically variable. For example, motor-driven rotary capacitors are known, the capacitance value of which can be changed by changing the arrangement of the capacitor plates relative to one another.

A plasma can, in a general sense, be assigned to three impedance regions. Very high impedances are present before ignition. In normal operation, i.e., during operation as intended with plasma, lower impedances are present. Very small impedances can occur in the case of undesirable local discharges (arcs) or plasma fluctuations. In addition to these three identified impedance regions, other special conditions with other associated impedance values can occur. If the load impedance changes suddenly and the load impedance or the transformed load impedance moves out of a permissible impedance region, the RF generator or transmission devices between the RF generator and the plasma chamber can be damaged. Stable states of the plasma can also be present that are undesirable.

An impedance matching circuit is described, for example, in the document DE 10 2009 001 355 A1.

Depending on the plasma process, a plasma can be operated with a pulsed or a continuous RF signal, also called a CW signal. Due to the high variance that can occur in plasma processes, reproducible plasma ignition is an important issue for the safe operation of a plasma process. Reproducible ignition is less problematic with an RF generator that provides a CW signal because an impedance matching circuit can be configured at the beginning to ensure ideal ignition conditions (matching to “cold” impedance). After ignition, the impedance matching circuit is then regulated so that matching occurs as quickly as possible. With a CW signal, there is sufficient time therefor. However, reliable ignition is more problematic with an RF generator that produces a pulsed radio frequency signal. In pulsed operation, the impedance matching circuit is regulated to the “burning position”. This might not be optimal for ignition.

### SUMMARY

In an embodiment, the present disclosure provides a plasma process supply system for pulsed plasma processes, comprising an RF generator comprising at least one amplifier circuit, an impedance matching circuit, and a controller, the plasma process supply system being configured to connect to a plasma chamber. The RF generator is connected to the impedance matching circuit, the impedance matching circuit being configured to set a target impedance as an input impedance for the RF generator. The controller is configured to set the target impedance such that a trajectory describing an impedance curve for the input impedance within a settling period runs from a starting impedance region through an ignition impedance region to a target impedance region. The RF generator in the ignition impedance region delivers a power level that is higher than a target power level in the target impedance region.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 illustrates an exemplary embodiment of a plasma process supply system having a control device;

FIG. 2 an exemplary embodiment of an amplifier circuit of an RF amplifier of the plasma process supply system;

FIG. 3A, FIG. 3B, FIG. 3C, FIG. 3D and FIG. 3E illustrate examples of how a trajectory can run that describes an impedance curve for an input impedance during a settling period;

FIG. 4A and FIG. 4B illustrate curves for output power level delivered by an RF generator;

FIG. 5A and FIG. 5B illustrate exemplary embodiments of how an impedance matching circuit can be constructed;

FIG. 6 and FIG. 7 illustrate exemplary embodiments of how a measuring unit can be designed to measure a current and a voltage; and

FIG. 8 illustrates a flowchart for a method which explains the operation of the control device.

### DETAILED DESCRIPTION

In an embodiment, the present disclosure provides a plasma process supply system which, particularly in pulsed plasma processes, allows reliable ignition of the plasma at the beginning of each pulse.

The plasma process supply system is particularly suitable for pulsed plasma processes. It features an RF generator that comprises at least one amplifier circuit. Furthermore, the plasma process supply system comprises an impedance matching circuit and a control device. The plasma process supply system can be connected to a plasma chamber. The RF generator is (galvanically) connected to the impedance matching circuit. The impedance matching circuit is designed to set a target impedance as the input impedance for the RF generator. The target impedance is set, in particular, at an input of the impedance matching circuit to which the RF generator is connected. The control device is designed to set the target impedance such that a trajectory describing an impedance curve for the input impedance within a settling period runs from a starting impedance region through an ignition impedance region to a target impedance region, wherein the RF generator in the ignition impedance region outputs a power level that is higher than a target power level in the subsequent target impedance region. The target impedance lies within the target impedance region. Amplifiers generally exhibit a characteristic behavior with respect to the output power level depending on the load impedance. This behavior can also be described as the power profile of an RF amplifier. Choosing the right target impedance has the great advantage that the appropriate impedances are traversed at a speed that a controller could not regulate within that time. This is especially true when using a pulsed radio frequency signal, for which a controller would need to regulate each pulse individually. The target power level output from the RF generator can be the same across the entire impedance curve. In fact, a portion of the power level is always reflected in the different impedance regions. Therefore, the trajectory is chosen such that less reflected power level is expected in the ignition impedance region when the plasma is ignited than in the target impedance region.

It is particularly advantageous here that the trajectory, which passes through various regions up to the target impedance region, is set by selecting the target impedance in such a way that it passes through an ignition impedance region in which the RF generator delivers a higher power level than in the later target impedance region. This higher power level (power peaking) ensures a short-term increase in the field strength in the plasma chamber, which makes the plasma ignite more reliably than with conventional plasma process supply systems. Furthermore, it is particularly advantageous that the process can be unregulated until the target impedance region of the curve of the trajectory is reached, which significantly simplifies operation. The fact that the RF generator does not immediately see the target impedance is due, among other things, to the fact that the impedance matching circuit has a high quality factor, and the corresponding resonant circuits, which are formed, for example, from capacitors and inductors, must first settle into a stable position. Passive components oscillate, at least within the starting impedance region. For this reason, the impedance changes during the aforementioned settling period. Besides the impedance matching circuit, the consumer is also responsible for the formation of the curve of the trajectory. The plasma impedance also changes during the settling period. Since there are a variety of target impedances to achieve a desired target power level output from the RF generator, the target impedance can be selected at which the trajectory passes through a desired ignition impedance region, i.e., a region within which the power level output by the RF generator exceeds the target power level. For the actual plasma process, the increased power level that can be accessed in the ignition impedance region is often unnecessary, or the continuous use of this increased power level is avoided for efficiency reasons.

In an aspect, the settling period comprises the time range from the beginning of a pulse of the RF signal until a point in time at which the impedances no longer change, or until a change in the impedances is less than a threshold value. The impedances include the impedances of the impedance matching circuit (capacitors, coils) as well as the plasma impedance.

In an aspect, the amplifier circuit comprises a balanced amplifier. The use of balanced amplifiers offers significant advantages in plasma applications because they deliver their maximum power level when they encounter an input impedance that matches the nominal impedance (for example, 50 ohms). They are also more robust and have a constant output resistance. One problem arises when igniting the plasma, which is resolved by choosing the target impedance and thereby improving the curve of the trajectory. For this reason, the plasma process supply system allows the use of balanced amplifiers. The balanced amplifier is preferably dimensioned such that its target power level is sufficient to operate the plasma process when the target impedance is present, with the increased power level in the matching region being used to ignite the plasma process.

The balanced amplifier preferably has two amplifier paths that are operated with a phase shift of preferably 90°. Such a balanced amplifier is described, for example, in WO2015/091468 A1 as a “Power converter”. WO2015/091468 A1 is hereby incorporated in its entirety into this disclosure by reference.

The balanced amplifier preferably comprises a 90° coupler for coupling the output signals of the amplifier paths.

The balanced amplifier preferably features a hybrid coupler for coupling the output signals of the amplifier paths.

The balanced amplifier preferably has a 3 dB coupler for coupling the output signals of the amplifier paths.

In an aspect, the control device is designed to set the target impedance in such a way that the RF generator delivers the preset target power level when the target impedance is present. As already explained, there are a variety of target impedances at which the RF generator delivers the same target power level output. It is also advantageous that the target power level can be specified.

In an aspect, the control device comprises a storage device. The storage device contains corresponding target impedances for different target power level outputs that can be delivered by the RF generator. For a given target power level, one target impedance can be defined, or a plurality of target impedances can be defined. The data can be stored, for example, in the form of a look-up table.

In an aspect, the control device is designed to set the target impedance to such a value that the trajectory passes through the ignition impedance region at which the RF generator delivers a power level that is a presentable amount above the target power level. Here too, it is advantageous that the size can be preset. A user can specify that the power level in the ignition impedance region should be, for example, 10% or 20% higher than the target power level. Preferably, the ignition impedance region in the Smith chart of a balanced amplifier is closer to 50 ohms than the target impedance region.

In an aspect, the plasma process supply system comprises an operating unit. The control device is designed to receive user input from the operating unit. The user input is the target power level and/or the preset amount by which the power level in the ignition impedance region exceeds the target power level. It is particularly advantageous that the operator of the plasma process supply system need only specify the target power level and the increased power level in the ignition impedance region, and thereby receives a reliably igniting plasma process.

In an aspect, the control device is designed to set the target impedance to such a value for which the trajectory passes through the ignition impedance region and the target impedance region, wherein the amplifier circuit and, in particular, amplifier elements of the amplifier circuit have a power level loss that is below a threshold value, thereby minimizing the power level loss in particular. By measuring the amplifier circuit, it is made possible to determine the regions where the efficiency is above a threshold value or where the power level loss occurring in the individual amplifier elements (for example, in the transistors) is below a threshold value. Choosing a corresponding trajectory is particularly advantageous because, when using a balanced amplifier, it is not operated with matching in the target impedance region, and therefore a signal power level is reflected back from the impedance matching circuit to the RF amplifier.

In an aspect, the control device is designed to set the target impedance to a value such that an average value of the impedance curve corresponds to the nominal impedance of the RF generator, in particular 50 ohms. This improves efficiency.

In an aspect, the control device is designed to measure the impedance curve of a trajectory and to adjust the target impedance based on the measured impedance curve, so that the trajectory exhibits an improved curve in a subsequent settling period. This has the advantage, especially in pulsed plasma applications, that the trajectory can be successively adjusted to the optimal curve. If a repetition rate (pulse rate) of preferably more than 10 Hz to preferably less than 1 MHz is used, the desired trajectory is achieved very quickly.

In an aspect, this can improve the curve of the trajectory in a subsequent settling period with regard to the efficiency of the amplifier circuit, the achievable power level in the ignition impedance region, the average impedance within the settling period, and/or the achievable power level in the target impedance region.

In an aspect, the control device is designed to measure the trajectory during each settling period. This allows the target impedance to be adjusted more precisely, to simultaneously check whether the curve of the trajectory is improved in the subsequent settling period (for example, in the subsequent pulse). With a high pulse repetition rate, it is not necessary to measure the trajectory during the settling period for each pulse. In this case, the trajectory for the settling period of at least every nth pulse, where n=2, 5, 10, 50, 100, 500, 1000, 5000, 10,000, can be measured.

In an aspect, the RF generator is designed to pulse a radio frequency signal and output this pulsed radio frequency signal to the impedance matching circuit. The settling period extends over the duration of such a pulse. The pulse repetition rate can range from approximately 10 Hz to 1 MHz. The pulse length can be in the range of 1 μs to 500 μs, particularly in the range of 100 μs to 500 μs, and most preferably at 300 μs. The settling period can comprise any time range of each pulse (e.g., 5% or more and 90% or less). The settling period depends in particular on the pulse length. If a pulse has a long pulse length, the settling period is shorter relative to the length of the pulse compared to a pulse with a shorter length.

In an aspect, the control device is designed to measure the trajectory for each settling period and thus for each pulse of the radio frequency signal. This allows for particularly precise adjustment of the target impedance. It is also provided that after a measured trajectory for a pulse, at least n pulses follow for which no trajectory is measured, with n>2, 3, 5, 10, 15, 20, 50, 100, 500. If a high pulse rate, e.g., 1 MHz, is used, it is not necessary to measure the trajectory of each pulse.

In an aspect, the control device comprises a measuring unit. The measuring unit comprises at least one directional coupler unit for measuring the power level of a forward and reverse radio frequency signal, or a current sensor and a voltage sensor. The control device is designed to measure the impedance curve of the trajectory based on the measurement result of the directional coupler unit or the current sensor and the voltage sensor. In this way, the impedance curve of the trajectory can be measured very easily and very quickly.

In an aspect, the voltage sensor of the measuring unit is a capacitive voltage divider, wherein a first capacitance is formed by an electrically conductive ring or cylinder through which a cable, carrying the RF power level, can be routed. In addition, the current sensor of the measuring unit is a coil which is arranged around the conductive ring or cylinder. This design enables a contactless measurement of current and voltage.

In an aspect, the measuring unit is located between the RF generator and the impedance matching circuit. Preferably, the measuring unit is arranged closer to the impedance matching circuit than to the RF generator.

In an aspect, the ignition impedance region is traversed by the trajectory temporally faster than it remains in the target impedance region. The impedance that the RF generator sees at its output over time (trajectory) traverses the ignition impedance region faster than it remains within the target impedance region. This allows for a stable plasma process with more reliable ignition.

In an aspect, the trajectory passes through the ignition impedance region in less than 30%, 20%, or 10% of the time it remains in the target impedance region.

In an aspect, a DC generator is provided which is designed to generate a DC signal, whereby the DC signal can be supplied to the plasma chamber in overlap with the radio frequency signal. The DC signal can be output constantly or pulsed by the DC generator. The impedance matching circuit can have an additional input to which the DC generator is connected. A bias tee can also be connected between the impedance matching circuit and the plasma chamber, which is designed to overlap the radio frequency signal and the DC signal and transmit them to the plasma chamber.

In an aspect, the impedance matching circuit comprises at least one or a plurality of adjustable reactances to change the transformation ratio for the impedance between an input, to which the RF generator is connected, and an output, to which a load, namely the plasma chamber, can be connected. The reactances are mechanically adjustable and/or electrically adjustable. This can be achieved, for example, through semiconductor switching elements such as transistors or PIN diodes. Additionally or alternatively, at least one varactor and/or at least one switchable inductor and/or capacitor can be used.

The method is used to operate the plasma process supply system. Pulsed plasma processes, in particular, can be operated using this method. The plasma process supply system comprises an RF generator which comprises at least one amplifier circuit, an impedance matching circuit, and a control device. The plasma process supply system can be connected to a plasma chamber. In the first step of the process, the RF generator is connected to the impedance matching circuit. In a second method step, a target impedance is defined as the input impedance for the RF generator, so that a trajectory describing an impedance curve for the input impedance within a settling period runs from a starting impedance region through an ignition impedance region to a target impedance region. The RF generator outputs a power level in the ignition impedance region that is higher than a target power level in the subsequent target impedance region. In a third method step, a target impedance is set as the input impedance for the RF generator by the impedance matching circuit.

Embodiments of the present disclosure are described below by way of example with reference to the drawings.

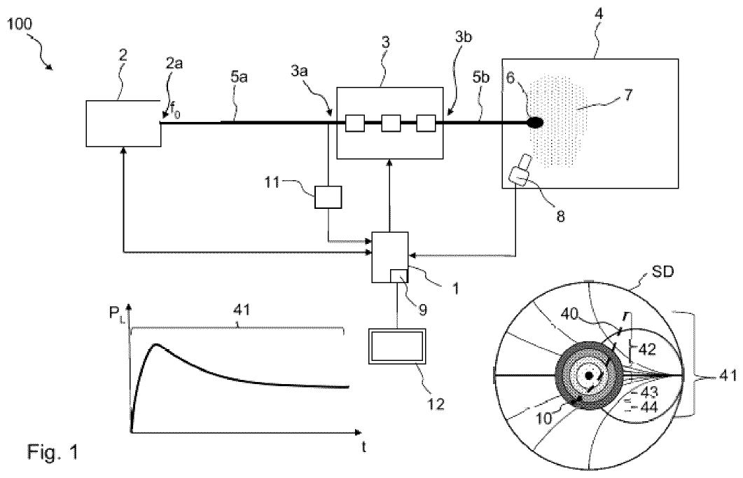

FIG. 1 shows a plasma process supply system 100 which comprises a control device 1. The plasma generation system 100 further comprises an RF generator 2, an impedance matching circuit 3, and at least one consumer 4, in particular in the form of a plasma chamber. The RF generator 2 is designed to supply a radio frequency signal, in particular in the form of a pulsed radio frequency signal, with a nominal power level P_{Nenn} and a frequency f₀, and to output it at an output terminal 2a. The impedance matching circuit 3 comprises an input terminal 3a, wherein the RF generator 2 is connected to the input terminal 3a via a first cable connection 5a. The impedance matching circuit 3 further comprises an output terminal 3b. The output terminal 3b is connected to the at least one consumer 4 via a second cable connection 5b. The first and/or second cable connection 5a, 5b can comprise one or a plurality of cables, for example connected in series and/or in parallel. Coaxial cables are preferably used.

The consumer 4, i.e., the plasma chamber, comprises at least one electrode 6 for generating a plasma 7. The electrode 6 is (galvanically) connected to the output terminal 3b of the impedance matching circuit 3. In this exemplary embodiment, a camera system 8 is arranged in the plasma chamber, which is designed to monitor the plasma 7.

The control device 1 is preferably a processor and/or FPGA and/or microcontroller and/or ASIC. The control device 1 can also comprise a storage device 9.

The control device 1 is designed to control the RF generator 2, in particular to activate or deactivate it. Additionally or alternatively, the control device 1 is also designed to change the power level and/or frequency of the RF signal by correspondingly controlling the RF generator 2. Additionally or alternatively, the control device 1 is designed to change the waveform (type of radio frequency signal, modulation of the RF signal, pulse duration, pulse repetition rate) of the radio frequency signal by correspondingly controlling the RF generator 2.

The control device 1 is likewise preferably designed to control the impedance matching circuit 3. In particular, the control device 1 is designed to change the transformation ratio within the impedance matching circuit 3 or to specify a target impedance 10 that acts as the input impedance for the RF generator 2.

The control device 1 also comprises a measuring unit 11. The measuring unit 11 is designed to measure, among other things, the value of the impedance at the input terminal 3a of the impedance matching circuit 3. The measuring unit 11 is preferably arranged between the RF generator 2 and the impedance matching circuit 3.

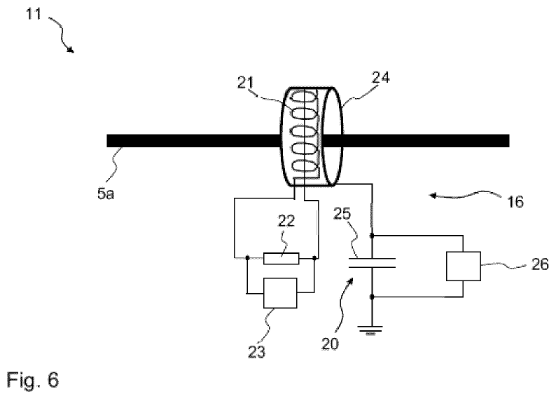

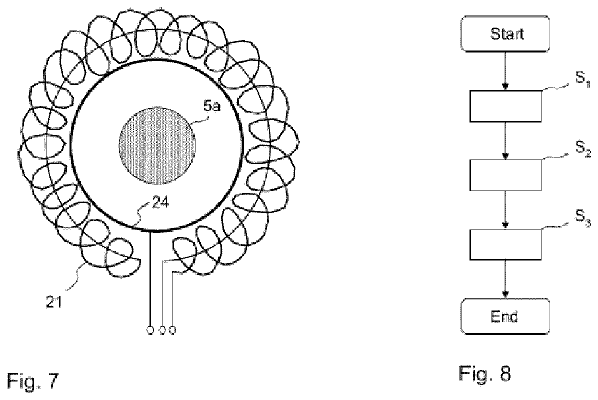

For this purpose, the measuring unit 11 comprises a directional coupler unit. The measuring unit 11 can measure the power level of a forward and reverse radio frequency signal on the first cable connection 5a via the directional coupler unit to calculate the input impedance therefrom. The measuring unit 11 can alternatively also comprise a current sensor 16 and a voltage sensor 20. A design with a current sensor 16 and a voltage sensor 20 is shown in FIGS. 6 and 7. The control device 1 is designed to calculate the impedance seen by the RF generator 2 based on the measurement result of the directional coupler unit or the current sensor 16 and the voltage sensor 20.

The plasma generating system 100 preferably also comprises an operating unit 12. The operating unit 12 is preferably a screen, in particular a touch-sensitive screen. In addition to a screen, the operating unit 12 can also comprise input means such as a keyboard and/or mouse. The operating unit 12 can also be a web server that provides data and receives user input. The control device 1 is designed so as to display current settings of the RF generator 2 and/or the impedance matching circuit 3 on the operating unit 12.

The control device 1 is preferably designed to receive setpoint specifications, for example for the power level of the radio frequency signal, what is termed the target power level. Furthermore, the frequency of the radio frequency signal and/or the waveform of the radio frequency signal and/or the pulse rate and/or the pulse duration for the radio frequency signal can be received by the operating unit 12. From this, corresponding control variables for the RF generator 2 and the impedance matching circuit 3 can be generated and transferred thereto.

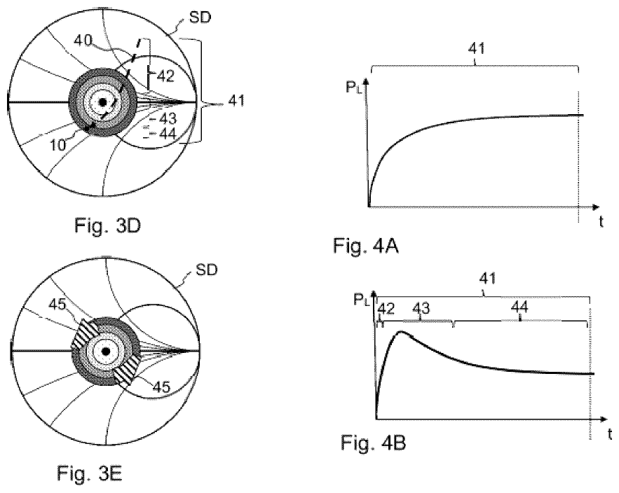

FIG. 1 also shows:
An example of the curve of a trajectory 40 in a Smith chart SD, which describes an impedance curve for an input impedance 10 within a settling period 41, which runs from a starting impedance region 42 through an ignition impedance region 43 to a target impedance region 44. This is described in detail below in FIG. 3D.
An example of the curve of an output power level P_{L} over the time t that an RF generator 2 emits within a settling period 41. This is described in detail below with reference to FIG. 4B.

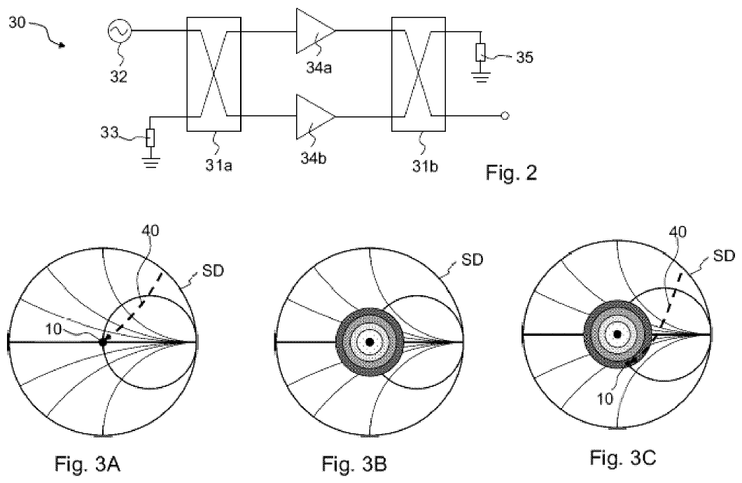

FIG. 2 shows an exemplary setup of an amplifier circuit 30 of the RF amplifier 2. Amplifier circuit 30 comprises a balanced amplifier. In principle, amplifier circuit 30 could also comprise an unbalanced amplifier. The balanced amplifier has a first 3 dB coupler 31a and a second 3 dB coupler 31b, which are designed in particular in the form of a hybrid coupler. A first input of the first 3 dB coupler 31a is connected to a signal source 32. The signal source 32 is designed to generate the radio frequency (pulsed) signal. A second input of the first 3 dB coupler 31a is connected to the reference ground via a resistor 33. A first output of the first 3 dB coupler 31a is connected to a first amplifier 34a, in particular in the form of a transistor amplifier. A second output of the first 3 dB coupler 31a is connected to a second amplifier 34b, in particular in the form of a transistor amplifier. The first transistor amplifier 34a is connected via its output to a first input of the second 3 dB coupler 31b. The second transistor amplifier 34b is connected at its output to a second input of the second 3 dB coupler 31b. A first output of the second 3 dB coupler 31b is connected to the reference ground via the resistor 35. In the case of a mismatch, which is deliberately induced as explained below, it depends, depending on the target impedance 10, on whether power level reflected back into the RF amplifier 2 is converted into heat in the resistor 35 or in the first and/or second transistor amplifier 34a, 34b. The aim is that any power level that is reflected back is converted into heat in the resistor 35, because this can easily be adequately dimensioned. A second output of the second transistor amplifier 34a, 34b, which can be the output terminal 2a, is connected to the impedance matching circuit 3.

FIGS. 3A, 3B, 3C, 3D, and 3E show various examples of how a trajectory 40 can run in a Smith chart SD, which describes an impedance curve for an input impedance 10 within a settling period 41. A trajectory 40 describes an impedance curve over time. Such a trajectory 40 is shown as a dashed line in the figures mentioned.

In FIG. 3A, the trajectory 40 runs within a settling period 41 (see FIGS. 4A, 4B) in the direction of a point on a Smith chart SD, which corresponds to an impedance of 50 ohms. In this case, this impedance is the target impedance 10. With a balanced amplifier, adjustment is made at this point, and the balanced amplifier delivers the maximum power level. The ignition behavior of plasma 7 is problematic here. If maximum efficiency is not absolutely necessary here, it could be advantageous to choose a target impedance 10 that is distant from the nominal impedance. In this case, a mismatch would be deliberately created. This is shown, for example, in FIGS. 3C and 3D.

FIG. 3B illustrates that there are different impedance regions for a balanced amplifier in which the balanced amplifier delivers the same power level. These regions have the same hatching in FIG. 3B and extend approximately in a circle around the point of nominal impedance. If a user specifies a target power level output, different target impedances 10 can be selected so that the RF amplifier 2 delivers the desired target power level output. Not all of these target impedances 10 are useful; for example, there are target impedances where the RF amplifier 2 delivers the desired power level, but the individual transistor amplifiers 34a, 34b are subjected to different loads. The closer the hatched regions are to the point of nominal impedance, the higher the output power level that the RF amplifier 2 can provide.

FIG. 3C describes the curve of a trajectory 40 in the direction of the target impedance 10. Due to a settling process in the impedance matching circuit 3 and also in the plasma chamber 4, the target impedance 10 is not reached immediately. Instead, a trajectory 40, i.e., an impedance curve over time, can be measured, at the end of which the target impedance is reached. This means that the RF generator 2 does not immediately see the target impedance 10 at its output. In FIG. 3C, the RF generator 2 provides the desired output power level (outermost circle) when the target impedance 10 is reached, at the end of trajectory 40. The problem is that until the target impedance 10 is reached, the RF generator 2 only sees impedances where it cannot provide the required power level for the radio frequency signal necessary for a reliable ignition of the plasma 7.

According to the development presented here, the control device 1 is designed to set the target impedance 10 in such a way that a trajectory 40 runs from a starting impedance region 42 through an ignition impedance region 43 to the target impedance region 44, wherein the RF generator 2 delivers a power level in the ignition impedance region 43 that is higher than the target power level in the subsequent target impedance region 44, where the target impedance 10 is located. This situation is illustrated in FIG. 3D. In the target impedance region 44, the RF amplifier 2 outputs a radio frequency signal with approximately the same power level as in the target impedance region 44 from FIG. 3C. In FIG. 3D, the trajectory 40 passes through the ignition impedance region 43, in which impedances are present that cause the RF amplifier 2 to output a higher power level than in the later target impedance region 44, resulting in a more reliable ignition of the plasma 7. As explained, a user can enter the desired power level output from the RF amplifier 2 in the ignition impedance region 41.

Depending on the selected target power level, which can be specified by a user, and the desired power level in the ignition impedance region 43, which can also be specified by a user, the appropriate target impedance 10 is selected. The measuring unit 11 enables the control device 1 to continuously measure the impedance curve and to adjust the target impedance 10 so that the trajectory 40 passes through the desired ignition impedance region 43. In the storage device 9, a power level can be stored for each target impedance 10, which is adjustable by the impedance matching circuit 2, which the RF amplifier 2 can deliver when the target impedance 10 is reached.

FIG. 3E shows that there are regions 45 through which the trajectory 40 should not pass. This can be due, for example, to impedances that cause the transistor amplifiers 34a, 34b to be excessively or unevenly loaded and/or to be insufficiently efficient due to a power level reflected back to the RF amplifier 2. It is therefore the task of the control device 1 to ensure, by selecting the target impedance 10, that the trajectory 40 does not pass through the regions 45 or only for a very short period within the settling period 41.

FIGS. 4A and 4B each show a curve of the output power level P_{L} over time t.

FIG. 4A shows a settling period 41, such as that found in the trajectory 40 from FIG. 3A. The target impedance in FIG. 3A is at the nominal impedance, in this case 50 ohms, where the amplifier circuit 30 is a balanced amplifier that delivers maximum power level at the nominal impedance. Therefore, the power level output of the RF amplifier 2 in FIG. 4A increases with increasing time within the settling period 41.

FIG. 4B, on the other hand, shows a settling period 41, as is the case, for example, with the trajectory 40 from FIG. 3D. The trajectory 40 runs via a starting impedance region 42 to an ignition impedance region 43 and on to a target impedance region 44. The power level output of the RF amplifier 2 is higher in the ignition impedance region 43 than in the target impedance region 44. This results in a more reliable ignition of plasma 7. It is also clearly visible that the target impedance region 44 lasts the longest in relation to the entire duration of the settling period 41. The ignition impedance region 43 extends over a shorter period, preferably less than 30%, 20%, or less than 10% of the time period over which the target impedance region 44 extends.

If the radio frequency signal is a pulsed radio frequency signal, then the settling period 41 could, for example, be the pulse duration. In this case, the control device 1 is preferably designed to measure the trajectory 40 again for each pulse, i.e., for each new settling period 41. It can adjust the target impedance 10, preferably while the target power level (specified by the user) remains unchanged, to positively influence the curve of the trajectory 40, i.e., in particular to ensure that a sufficiently high power level is delivered by the RF generator 2 in the ignition impedance region 43.

To transform the plasma impedance to the input impedance of the RF generator 2, the impedance matching circuit 3 can comprise one or a plurality of (series-connected) transformation stages.

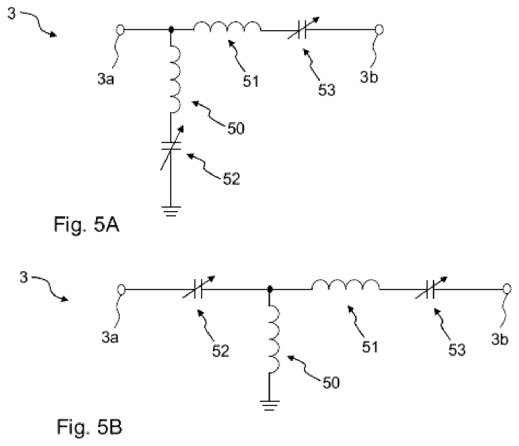

One such transformation stage is shown, for example, in FIGS. 5A and 5B. If the impedance matching circuit 3 contains a plurality of transformation stages, each transformation stage can be constructed according to the exemplary embodiment of FIGS. 5A, 5B. It is understood that the impedance matching circuit 3 can also be designed differently than shown in FIGS. 5A, 5B.

The input terminal 3a of the impedance matching circuit 3 is connected in FIG. 5A to a first coil 50 (first inductance) and to a second coil 51 (second inductance). The first and second coils 50, 51 are connected with their first terminal to a common node and thus to the input terminal 3a of the impedance matching circuit 3. The first coil 50 is connected to a reference ground via a first capacitor 52 (first capacitance). The second coil 51 is connected to the output terminal 3b via a second capacitor 53 (second capacitance). The first and/or second capacitors 52, 53 are adjustable components, in particular in the form of rotary capacitors, the capacitance of which can be changed via stepper motors. Alternatively, solid-state switches can be used to add and remove capacitances as quickly as possible. In particular, the plate spacing of the first and second capacitors 52, 53 can be changed. The control device 1 is so designed as to control the respective stepper motors accordingly. The capacitances of the first and second capacitors 52, 53 can be adjusted independently of each other. Preferably, impedance matching circuit 3 is free of additional components. Of course, the position of the first coil 50 and the first capacitor 52 can also be exchanged. In this case, the first capacitor 52 is arranged at the input terminal 3a of the impedance matching circuit 3 and the first coil 50 is arranged at the reference ground. Additionally or alternatively, the position of the second coil 51 and the second capacitor 53 can also be exchanged. In this case, the second capacitor 53 is arranged at the input terminal 3a of the impedance matching circuit 3 and the second coil 51 is arranged at the output terminal 3b of the impedance matching circuit 3.

The input terminal 3a of the impedance matching circuit 3 is connected to the first capacitor 52 (first capacitance) in FIG. 5B. The first capacitor 52 is connected to both the first coil 50 (first inductance) and the second coil 51 (second inductance). This is done via a common node, to which both the first capacitor 52 and the first and second coils 50, 51 are connected. The first coil 50 is still connected to the reference ground. The second coil 51 is connected (series connection) to the second capacitor 53 (second capacitance). The second capacitor 53 is connected to the output terminal 3b of the impedance matching circuit 3. The position of the second coil 51 and the second capacitor 53 could also be reversed. In this case, the second capacitor 53 would be connected to the common node and the second coil 51 would be connected to the output terminal 3b of the impedance matching circuit 3. Preferably, impedance matching circuit 3 is free of additional components.

FIGS. 6 and 7 show an exemplary embodiment of a structure of the measuring unit 11. The measuring unit 11 is designed to measure voltage and current without contact.

For this purpose, the measuring unit 11 comprises a current sensor 16 and a voltage sensor 20.

It is preferable to measure the phase relationship between current and voltage so that the impedance can be calculated.

The current sensor 16 of the measuring unit 11 is a coil 21, in particular in the form of a Rogowski coil. Both ends of the coil are preferably connected to each other via a shunt resistor 22. The voltage, which drops across the shunt resistor 22, can be digitized by means of a first A/D converter 23.

The voltage sensor 20 of the measuring unit 11 is preferably built as a capacitive voltage divider. A first capacitor 24 is formed by an electrically conductive ring 24. An electrically conductive cylinder could also be used. The corresponding first cable connection 5a, is guided through this electrically conductive ring 24. A second capacitor 25 of the voltage sensor 20, which is constructed as a voltage divider, is connected to the reference ground. A second A/D converter 26 is connected in parallel to the second capacitor 25, and is designed to detect and digitize the voltage which drops across the second capacitor 25.

In principle, the measuring unit 11 can also be arranged or built on a (common) circuit board. The first capacitor 24 can be formed by a coating on a first and an opposite second side of the circuit board. In this case, the coatings on the first side and the second side are electrically connected to each other by vias. The first cable connection 5a is guided through an opening in the circuit board. The second capacitor 25 can be formed by a discrete component.

The current sensor 16 in the form of the coil 21, in particular in the form of the Rogowski coil, is spaced further apart from the first cable connection 5a than is the first capacitor 24. The coil can also be formed on the same circuit board by corresponding coatings and vias. The coil for current measurement and the first capacitor for voltage measurement preferably run through a common plane.

The shunt resistor 22 can also be arranged on this circuit board. The same applies to the first and/or second A/D converter 23, 23.

The measuring unit 11 can also be designed as a directional coupler unit.

In principle, the measuring unit 11 can also be arranged between the impedance matching circuit 3 and the load in the form of the plasma chamber 4. In this case, the second cable connection 5b would be used for measuring current and voltage. The input impedance can then be calculated by taking into account a known transformation ratio of the impedance matching circuit 3.

FIG. 8 describes the method used to operate the plasma process supply system 100. Pulsed plasma processes, in particular, can be operated using this method. The plasma process supply system 100 comprises an RF generator 2, which has at least one amplifier circuit 30, an impedance matching circuit 3, and a control device 1. The plasma process supply system 100 can be connected to a plasma chamber 4. In a joining method step S₁, the RF generator 2 is connected to the impedance matching circuit 3. In a defining method step S₂, a target impedance 10 is set as the input impedance for the RF generator 2 such that a trajectory 40, which describes an impedance curve for the input impedance within a settling period 41, runs from a starting impedance region 42 through an ignition impedance region 43 to a target impedance region 44. The RF generator 2 outputs a power level in the ignition impedance region 43 that is higher than a target power level in the subsequent target impedance region 44. Within a setting method step S₃, the impedance matching circuit 3 sets a target impedance 10 as the input impedance for the RF generator 2.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A plasma process supply system for pulsed plasma processes, comprising:
an RF generator comprising at least one amplifier circuit;
an impedance matching circuit; and
a controller, the plasma process supply system being configured to connect to a plasma chamber,
wherein the RF generator is connected to the impedance matching circuit, the impedance matching circuit being configured to set a target impedance as an input impedance for the RF generator,
wherein the controller is configured to set the target impedance such that a trajectory describing an impedance curve for the input impedance within a settling period runs from a starting impedance region through an ignition impedance region to a target impedance region, the RF generator in the ignition impedance region delivering a power level that is higher than a target power level in the target impedance region.

2. The plasma process supply system according to claim 1, wherein the amplifier circuit comprises a balanced amplifier.

3. The plasma process supply system according to claim 1, wherein the controller is configured to set the target impedance such that the RF generator delivers a preset target power level when the target impedance is present.

4. The plasma process supply system according to claim 3, wherein the controller comprises a storage, wherein corresponding target impedances for different target power level outputs that can be delivered by the RF generator, which are set by the impedance matching circuit, are stored in the storage.

5. The plasma process supply system according to claim 1, wherein the controller is configured to set the target impedance to such a value that the trajectory passes through the ignition impedance region at which the RF generator delivers a power level that is above the target power level by a preset amount.

6. The plasma process supply system according to claim 5, further comprising an operating unit, wherein the controller is configured to receive a user input from the operating unit, the user input comprising:
a) a level of the target power level, and/or
b) the preset amount by which the power level in the ignition impedance region exceeds the target power level.

7. The plasma process supply system according to claim 1, wherein the controller is configured to set the target impedance to such a value for which the trajectory passes through the ignition impedance region and the target impedance region, amplifier elements of the amplifier circuit having a power level dissipation that is below a threshold value.

8. The plasma process supply system according to claim 1, wherein the controller is configured to set the target impedance to a value such that an average value of the impedance curve over the settling period corresponds to a nominal impedance of the RF generator of 50 ohms.

9. The plasma process supply system according to claim 1, wherein the controller is configured to measure the impedance curve of a trajectory and to adjust the target impedance based on the measured impedance curve, so that the trajectory has an improved curve in a subsequent settling period.

10. The plasma process supply system according to claim 9, wherein the curve of the trajectory is in a subsequent settling period with respect to improving an:
a) efficiency of the amplifier circuit,
b) achievable power level within the ignition impedance region,
c) averaged impedance within the settling period, and/or
d) achievable power level within the target impedance region.

11. The plasma process supply system according to claim 1, wherein the controller is configured to measure the trajectory within each settling period or within each nth settling period, with n=2, 5, 10, 50, 100, 500, 1000, 5000, 10000.

12. The plasma process supply system according to claim 1, wherein the RF generator is configured to pulse a radio frequency signal and output the pulsed radio frequency signal to the impedance matching circuit, and
the settling period extends over a time length of a pulse of the radio frequency signal or a part thereof.

13. The plasma process supply system according to claim 12, wherein the controller is configured to measure the trajectory for each settling period and thereby for each pulse of the radio frequency signal.

14. The plasma process supply system according to claim 1, wherein the controller includes a measuring unit,
wherein the measuring unit comprises a directional coupler for detecting a power level of a forward and reverse radio frequency signal or a current sensor and a voltage sensor, and
wherein the controller is configured to measure the impedance curve of the trajectory based on a measurement result of the directional coupler or the current sensor and the voltage sensor.

15. The plasma process supply system according to claim 1, wherein the ignition impedance region is traversed by the trajectory temporally faster than the trajectory remains in the target impedance region.

16. The plasma process supply system according to claim 15, wherein the trajectory passes through the ignition impedance region in less than 50%, 40%, 30%, 20%, or 10% of the time that the trajectory remains within the target impedance region.

17. The plasma process supply system according to claim 1, comprising a DC generator configured to generate a DC signal, wherein the DC signal is configured to be supplied to the plasma chamber in overlap with the radio frequency signal.

18. The plasma process supply system according to claim 1, wherein the impedance matching circuit comprises at least one or a plurality of adjustable reactances to change the transformation ratio for the impedance between an input, to which the RF generator is connected, and an output, to which the plasma chamber is configured to be connected, and
wherein the adjustable reactances are mechanically adjustable and/or electrically adjustable and are formed by at least one varactor and/or at least one switchable inductance and/or capacitance and/or by at least one PIN diode.

19. A method for operating a plasma process supply system for pulsed plasma processes, the plasma process supply system having an RF generator comprising at least one amplifier circuit, an impedance matching circuit, and a controller, the plasma process supply system being configured to connect to a plasma chamber, the method comprising:
connecting the RF generator with the impedance matching circuit;
setting a target impedance as input impedance for the RF generator such that a trajectory describing an impedance curve for the input impedance within a settling period runs from a starting impedance region through an ignition impedance region to a target impedance region, the RF generator delivering a power level in the ignition impedance region that is higher than a target power level in the target impedance region; and
setting the target impedance as input impedance for the RF generator by the impedance matching circuit.
